(19) United States
(12) Patent Application Publication
(10) Pub. No.: US 2016/0276199 A1
(43) Pub. Date: Sep. 22, 2016

(54) DECOMPRESSION PROCESSING APPARATUS

(71) Applicant: DISCO CORPORATION, Tokyo (JP)

(72) Inventor: Hidekazu Iida, Tokyo (JP)

(21) Appl. No.: 15/070,763

(22) Filed: Mar. 15, 2016

(30) Foreign Application Priority Data
Mar. 16, 2015 (JP) 2015-051885

(51) Int. Cl. H01L 21/683; H01J 37/32

(52) U.S. Cl. CPC H01L 21/6833; H01J 37/32706; H01J 37/32743; H01J 37/32715; H01J 37/32568; H01J 37/32577; H01J 37/3244; H01J 37/32816; H01J 37/32027; H01J 2237/327; H01J 2237/334

(57) ABSTRACT

In a state in which a wafer held by a holding portion contacts with an attraction face of an electrostatic chuck after a loading unit loads the wafer into a chamber, the holding portion is connected to ground and a DC voltage is applied to a lower electrode. Then, the holding portion cancels the attraction of the wafer and is spaced away from the wafer thereby to charge the electrostatic chuck and the wafer with electric charge different in polarity from each other such that the wafer is attracted and held by the attraction face.

### BACKGROUND OF THE INVENTION

1. Field of the Invention

The present invention relates to a decompression processing apparatus wherein a wafer is held by an electrostatic chuck in a chamber and plasma is generated in the chamber to perform processing for the wafer.

2. Description of the Related Art

In a decompression processing apparatus such as a plasma etching apparatus, a process is performed for a wafer by placing the inside of a chamber into a vacuum state and generating plasma in the chamber. Therefore, if a vacuum attraction method is adopted for a chuck table for holding a wafer, then it is difficult to hold the wafer with certainty. Therefore, a decompression processing apparatus adopts an electrostatic attraction method which utilizes electrostatic attraction force to attract and hold a wafer (for example, refer to Japanese Patent No. 4938352).

An electrostatic chuck which electrostatically attracts a wafer is formed from an insulating substance having a high dielectric constant and has a lower electrode provided in the inside thereof. As the electrostatic chuck, two electrostatic chucks are available including an electrostatic chuck of the double electrode type which includes two lower electrodes and an electrostatic chuck of the single electrode type which includes a single lower electrode. When a wafer is to be divided by plasma etching, it is necessary to use an electrostatic chuck of the single electrode type in order to keep electrostatic attraction. In the electrostatic chuck of the single electrode type, when a high frequency voltage is applied to the electrostatic chuck in a state in which a wafer is placed on the electrostatic chuck, reaction gas supplied to a space between the lower electrode and an opposing upper electrode is placed into a plasma state, and the wafer is grounded through the plasma. Therefore, if a direct current (DC) voltage is applied to the lower electrode, then the insulating substance above the lower electrode is dielectrically polarized to generate electrostatic attraction force, by which the wafer is electrostatically attracted (for example, refer to Japanese Patent Laid-open No. 2005-347545).

### SUMMARY OF THE INVENTION

However, in order for a wafer to be attracted and held in a state in which no plasma exists, it is necessary for an electrostatic chuck of the single electrode type to be provided with grounding means for grounding the wafer.

Therefore, it is an object of the present invention to provide a decompression processing apparatus which makes it possible, in a state in which an electrostatic chuck of the single electrode type attracts and holds a wafer to perform plasma etching, to electrostatically attract the wafer without the necessity for disposing grounding means for exclusive use for grounding the wafer.

In accordance with an aspect of the present invention, there is provided a decompression processing apparatus for performing a working process for a wafer with reaction gas in the form of plasma, including an electrostatic chuck having an attraction face formed from an upper face formed on an insulating material and having a lower electrode in the inside thereof, the electrostatic chuck being configured to electrostatically attract a wafer to the attraction face, an upper electrode disposed above the electrostatic chuck in an opposing relationship to the attraction face of the electrostatic chuck, a chamber configured to accommodate the electrostatic chuck and the upper electrode therein, loading means for loading the wafer into the chamber and placing the wafer on the attraction face, decompression means for decompressing the inside of the chamber, gas supplying means for supplying the reaction gas into the chamber, and high frequency voltage application means for applying a high frequency voltage to the electrostatic chuck to form plasma from the reaction gas supplied into the chamber, the loading means including a holding portion having a conductive contacting portion contacting with the upper face of the wafer and configured to hold the wafer thereon, conduction means for establishing conduction of the holding portion to ground, and driving means for placing the wafer held by the holding portion on the electrostatic chuck, wherein, in a state in which the wafer held by the holding portion of the loading means contacts with the attraction face of the electrostatic chuck after the wafer is loaded into the chamber, the holding portion is connected to the ground by the conduction means and a DC voltage is applied to the lower electrode, whereafter the holding portion cancels the attraction of the wafer and is moved away from the wafer such that the electrostatic chuck and the wafer are charged with electric charge different in polarity from each other thereby to allow the wafer to be attracted and held by the attraction face of the electrostatic chuck.

In the present invention, since the loading means is connected to the ground, it holds and places a wafer on the electrostatic chuck and a voltage is applied to the electrostatic chuck to charge the wafer such that the electrostatic chuck holds the wafer by electrostatic attraction force. Thereafter, if the suction force of the loading means is canceled to allow the loading means to be spaced away from the wafer, then the charge remains accumulated in the water. Consequently, the state in which the wafer is held by the electrostatic chuck can be maintained. Accordingly, a wafer can be electrostatically attracted by the electrostatic chuck of the single electrode type in the atmospheric pressure.

The above and other objects, features and advantages of the present invention and the manner of realizing them will become more apparent, and the invention itself will best be understood from a study of the following description and the appended claims with reference to the attached drawings showing a preferred embodiment of the invention.

### BRIEF DESCRIPTION OF THE DRAWINGS

FIG. 1 is a cross sectional view depicting an example of a decompression processing apparatus;

FIG. 2 is a cross sectional view depicting an example of loading means;

FIG. 3 is a cross sectional view depicting a state in which a wafer held by the loading means is placed on an electrostatic chuck;

FIG. 4 is a cross sectional view depicting a state in which the wafer is electrostatically attracted by the electrostatic chuck;

FIG. 5 is a cross sectional view depicting a state in which the loading means is spaced away from the wafer electrostatically attracted by the electrostatic chuck;

FIG. 6 is a cross sectional view depicting a state in which plasma etching is performed for the wafer electrostatically attracted by the electrostatic chuck;

FIG. 7 is a cross sectional view depicting a state in which the wafer is electrostatically attracted by the electrostatic chuck after the plasma etching comes to an end;

FIG. 8 is a cross sectional view depicting a state in which the loading means is placed into contact with the wafer electrostatically attracted by the electrostatic chuck;

FIG. 9 is a cross sectional view depicting a state in which the loading means is placed into contact with the wafer electrostatically attracted by the electrostatic chuck to connect the wafer to ground; and

FIG. 10 is a cross sectional view depicting a state in which the loading means moves the wafer away from the electrostatic chuck.

### DETAILED DESCRIPTION OF THE PREFERRED EMBODIMENT

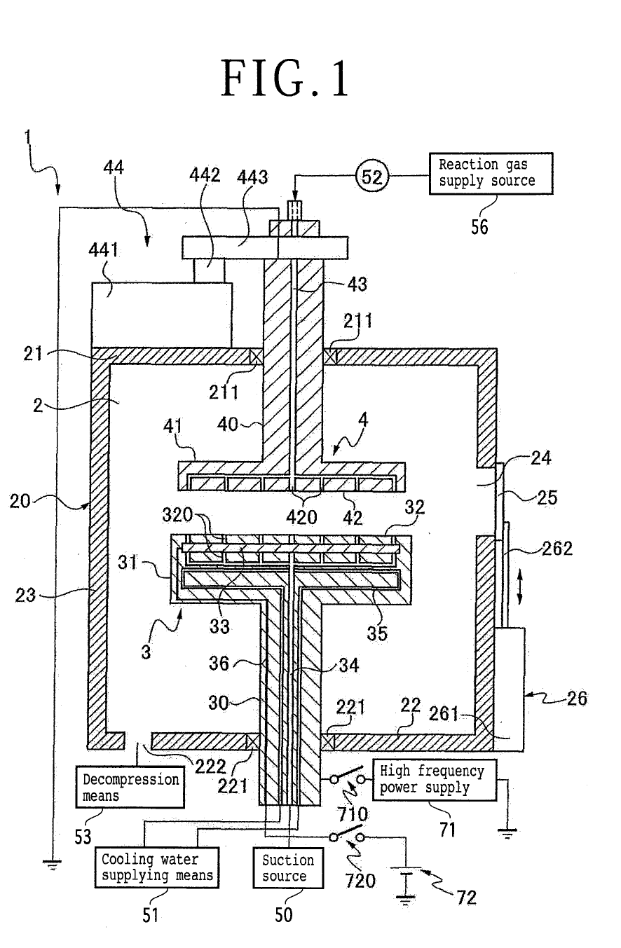

A plasma etching apparatus 1 depicted in FIG. 1 is an example of a decompression processing apparatus and includes a chamber 2 that is a space which is covered with a housing 20 and into which a wafer of a target of etching is to be accommodated.

The housing 20 is formed from an upper wall 21, a lower wall 22 and side walls 23, and an opening/closing port 24 is formed in one of the side walls 23. The opening/closing port 24 is openable and closable by a shutter 25. The shutter 25 is driven to move up and down by shutter opening/closing means 26. The shutter opening/closing means 26 is configured from a cylinder 261, and a piston 262 connected to the shutter 25 and driven to move up and down by the cylinder 261. In the inside of the chamber 2, an electrostatic chuck 3 for attracting and holding a wafer and an upper electrode 4 positioned above the electrostatic chuck 3 are accommodated.

The electrostatic chuck 3 is configured from a shaft portion 30 of a cylindrical shape formed from an insulating material, and a table unit 31 formed in a shape of a disk at an upper end of the shaft portion 30. Further, a high frequency power supply 71 is connected to the electrostatic chuck 3. Although not essentially required, a plurality of suction holes 320 which are open to an attraction face 32 which is an upper face of the table unit 31 are formed in the table unit 31. The suction holes 320 communicate a suction source 50 and the attraction face 32 with each other through a suction path 34. Further, a lower electrode 33 is provided in the inside of the table unit 31. The lower electrode 33 is connected to the positive electrode of a DC power supply 72 through a conduction portion 36 and a switch 720.

The shaft portion 30 is fitted in the lower wall 22 which configures the housing 20, and is sealed and held by an insulating member 221. Further, a cooling water flow path 35 circulates in a lower portion of the table unit 31 and the shaft portion 30. The cooling water flow path 35 is communicated with cooling water supplying means 51. The upper electrode 4 is disposed at a position above the electrostatic chuck 3 in an opposing relationship to the attraction face 32 of the electrostatic chuck 3 and is connected to the ground. The upper electrode 4 is configured from a cylindrical shaft portion 40 and a plate-shaped portion 41 formed in a shape of a disk at a lower end of the shaft portion 40. The shaft portion 40 is fitted in the upper wall 21 which configures the housing 20 and is sealed and held for upward and downward movement by an insulating member 211.

A plurality of gas jet holes 420 are formed in the plate-shaped portion 41 such that they are open to a lower face 42 of the plate-shaped portion 41. Gas supplying means 56 including reaction gas supply source 55 is connected to the gas jet holes 420 through a gas flow path 43 and a valve 52. For example, SF₆ gas is stored in the reaction gas supply source 55. By switching the valve 52, the reaction gas supply source 55 is communicated with the gas flow path 43 such that reaction gas can be fed into the chamber 2 through the gas jet holes 420. The reaction gas supplied to the chamber 2 is placed into a plasma state by a high frequency voltage applied to the electrostatic chuck 3 from the high frequency power supply 71.

The upper electrode 4 is driven to move up and down by lifting means 44. The lifting means 44 is configured from a cylinder 441, a piston rod 442, and a bracket 443 connected to the piston rod 442. The bracket 443 supports the upper electrode 4 thereon and is configured such that the cylinder 441 moves the piston rod 442 up and down thereby to move the upper electrode 4 supported on the bracket 443 up and down.

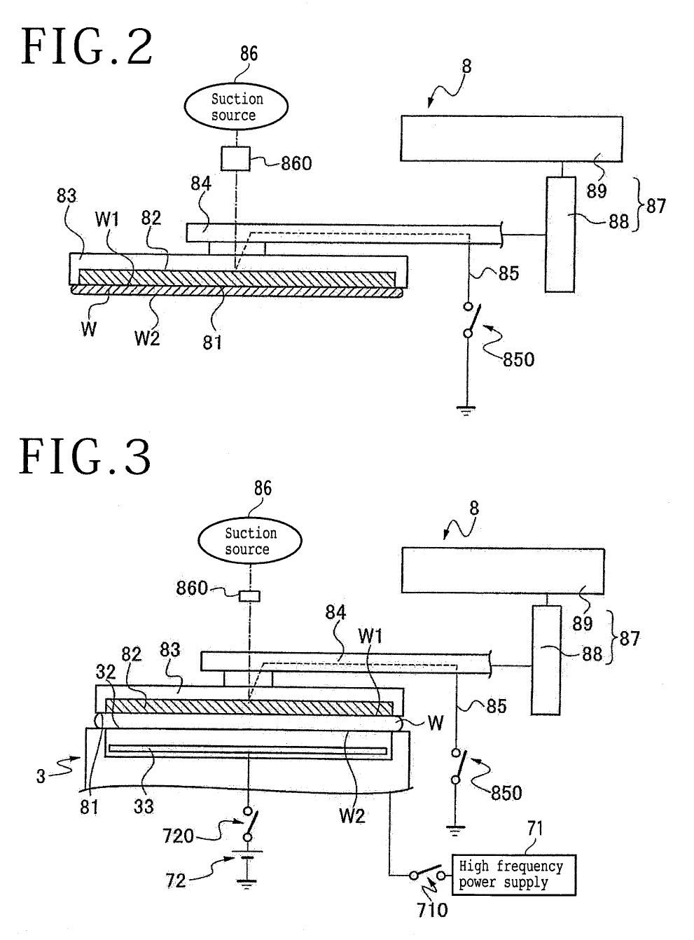

An opening/closing port 222 is formed in the lower wall 22 which configures the housing 20 and is communicated with decompression means 53 for decompressing the inside of the chamber 2. The decompression means 53 can suck gas in the inside of the chamber 2 to place the inside of the chamber 2 into a vacuum state. A wafer processed in the chamber is unloaded to the outside of the chamber 2 through the opening/closing port 24 formed in the side wall 23. In order to load a wafer into the inside of the chamber 2, for example, loading means 8 depicted in FIG. 2 is used.

The loading means 8 depicted in FIG. 2 includes a holding portion 82 having a contacting portion 81 for sucking and holding an upper face W1 of a wafer, a frame member 83 for holding a portion of the holding portion 82 other than the contacting portion 81, an arm portion 84 connected to the frame member 83, conduction means 85 for establishing a conduction state of the contacting portion 81 to the ground in a state in which a switch is on, a suction source 86 for exerting suction force to act upon the contacting portion 81, and driving means 87 for placing the sucked and held wafer on the electrostatic chuck 3. The conduction means 85 includes a switch 850 for switching between a state in which the contacting portion 81 and the ground are connected to each other and another state in which the contacting portion 81 and the ground are not connected to each other. Further, the suction source 86 and the holding portion 82 are connected to each other through an opening and closing valve 860. The driving means 87 includes upward/downward moving means 88 for moving the arm portion 84 up and down, and loading/unloading moving means 89 for loading and unloading the holding portion 82 and the frame member 83 into and from the chamber 2 through the opening/closing port 24.

The holding portion 82 is configured from a material having conductivity and has a suction hole or holes for sucking and holding a wafer. The suction hole or holes for sucking a wafer may be configured from a porous member. Now, a method of etching a wafer using the plasma etching apparatus 1 depicted in FIG. 1 is described.

First, the valve 860 depicted in FIG. 2 is turned on to establish communication between the holding portion 82 of the loading means 8 and the suction source 86 to suck and hold the upper face W1 of a wafer W to the holding portion 82. Then, the cylinder 261 configuring the shutter opening/closing means 26 depicted in FIG. 1 moves down the piston 262 to move down the shutter 25 to open the opening/closing port 24, and in this state, the loading/unloading moving means 89 moves the holding portion 82, frame member 83 and arm portion 84 into the chamber 2 to load the wafer W held on the holding portion 82 into the chamber 2. Then, as depicted in FIG. 3, in a state in which the switch 850 is turned off, the upward/downward moving means 88 moves down the wafer W to place the wafer W on the attraction face 32 of the electrostatic chuck 3. At this time, the switch 720 is in an open state, and no voltage is applied to the lower electrode 33.

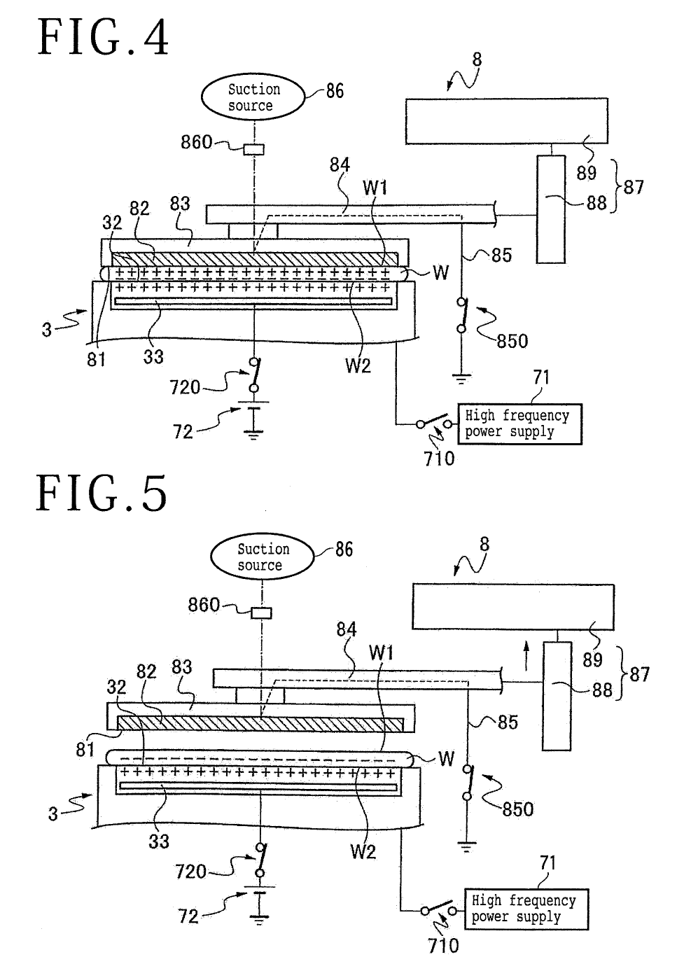

Then, as depicted in FIG. 4, in a state in which the lower face W2 of the wafer W contacts with the attraction face 32 of the electrostatic chuck 3, the switch 720 is turned on to apply a positive voltage to the lower electrode 33. Further, the switch 850 is turned on to connect the holding portion 82 of the loading means 8 to the ground. Consequently, positive charge is accumulated above the lower electrode 33, and negative charge is accumulated on the lower face W2 side of the wafer W while positive charge is accumulated on the upper face W1 side of the wafer W. Accordingly, the electrostatic chuck 3 and the wafer W are charged with electric charge different in polarity from each other, and the wafer W is placed into a state in which it is attracted and held by electrostatic attraction force to the attraction face 32. It is to be noted that the voltage to be applied to the lower electrode 33 may be a negative voltage.

Then, as depicted in FIG. 5, while the switch 720 and the switch 850 are kept on, the valve 860 is turned off to cancel the suction force acting upon the contacting portion 81 of the holding portion 82. Then, the upward/downward moving means 88 moves the arm portion 84, holding portion 82 and frame member 83 upwardly. Consequently, since the wafer W is attracted and held to the electrostatic chuck 3 by the electrostatic attraction force, the holding portion 82 of the loading means 8 is spaced way from the upper face W1 of the wafer W, and in a state in which the upper face W1 that is a working object face of the wafer W is exposed upwardly, the lower face W2 of the wafer W is attracted and held to the attraction face 32. Thereafter, the loading/unloading moving means 89 retracts the arm portion 84, holding portion 82 and frame member 83 to the outside of the chamber 2, and the shutter opening/closing means 26 moves down the shutter 25 to close up the chamber 2. At this time, the pressure in the chamber 2 is equal to the atmospheric pressure.

In this manner, if the holding portion 82 holds and places a wafer W on the electrostatic chuck 3 and a voltage is applied to the electrostatic chuck 3 while the holding portion 82 of the loading means 8 is connected to the ground and then the wafer W is charged such that the electrostatic chuck 3 holds the wafer W by electrostatic attraction force, whereafter the suction force of the holding portion 82 is canceled to remove the holding portion 82 from the wafer W, then the wafer W is kept in a charged state and a state in which the wafer W is held by the electrostatic chuck 3 can be maintained. Accordingly, the necessity for the grounding means for grounding the wafer W is eliminated. Further, as depicted in FIG. 1, it is more effective to have an auxiliary role of disposing the suction holes 320 which are communicated with the suction source on the attraction face 32 such that the wafer W is sucked and held by causing the suction holes 320 to suck the wafer W.

Then, in a state in which the upper face W1 which is a working object face of the wafer W is exposed in an upwardly directed state as depicted in FIG. 5, the decompression means 53 depicted in FIG. 1 decompresses the inside of the chamber 2 to establish a vacuum state. Then, the valve 52 is opened to allow, for example, SF₆ gas to be fed from the reaction gas supply source 55 into the gas flow path 43 such that the SF₆ gas is jetted downwardly through the gas jet holes 420.

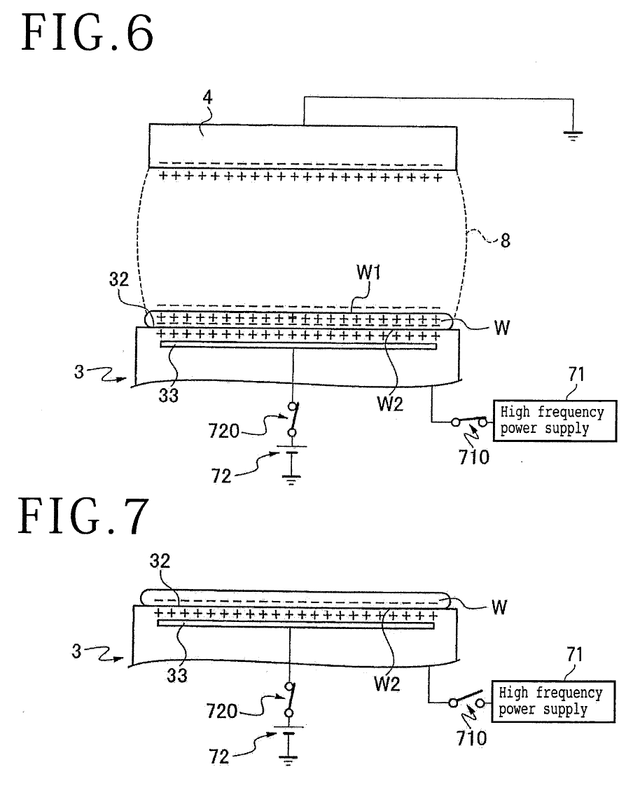

Then, as depicted in FIG. 6, a switch 710 is turned on while the switch 720 is kept on such that a high frequency voltage is applied between the wafer W and the upper electrode 4 from the high frequency power supply 71. Consequently, reaction gas is placed into a plasma state between the electrostatic chuck 3 and the upper electrode 4. The upper face W1 of the wafer W is etched by the plasma of the reaction gas. It is to be noted that the lower electrode 33 may be connected to the negative electrode of the DC power supply 72.

After the upper face W1 of the wafer W is etched by a desired amount, the supply of the reaction gas from the reaction gas supply source 55 into the chamber 2 is stopped, and the switch 710 is turned off to stop the application of a high frequency voltage between the electrostatic chuck 3 and the upper electrode 4 to stop formation of plasma from the reaction gas as depicted in FIG. 7. At this time, the switch 720 is left in an on state while the state in which a positive voltage is applied to the lower electrode 33 is maintained. After the formation of plasma from the reaction gas is stopped in this manner, a state in which no plasma exists between the lower electrode 33 and the upper electrode 4 is entered. However, since, during etching of the wafer W, the plasma exists between the electrostatic chuck 3 and the upper electrode 4 and the electrostatic chuck 3 and the upper electrode 4 remain in a conducting state therebetween, the wafer W is charged with static electricity, and a state in which the wafer W is held on the electrostatic chuck 3 by static electricity is established as depicted in FIG. 7.

In short, as long as a DC voltage is supplied from the DC power supply 72 to the lower electrode 33, since charge balanced with the DC voltage is held on the wafer W, the wafer W is held on the electrostatic chuck 3 without being influenced by whether or not plasma exists.

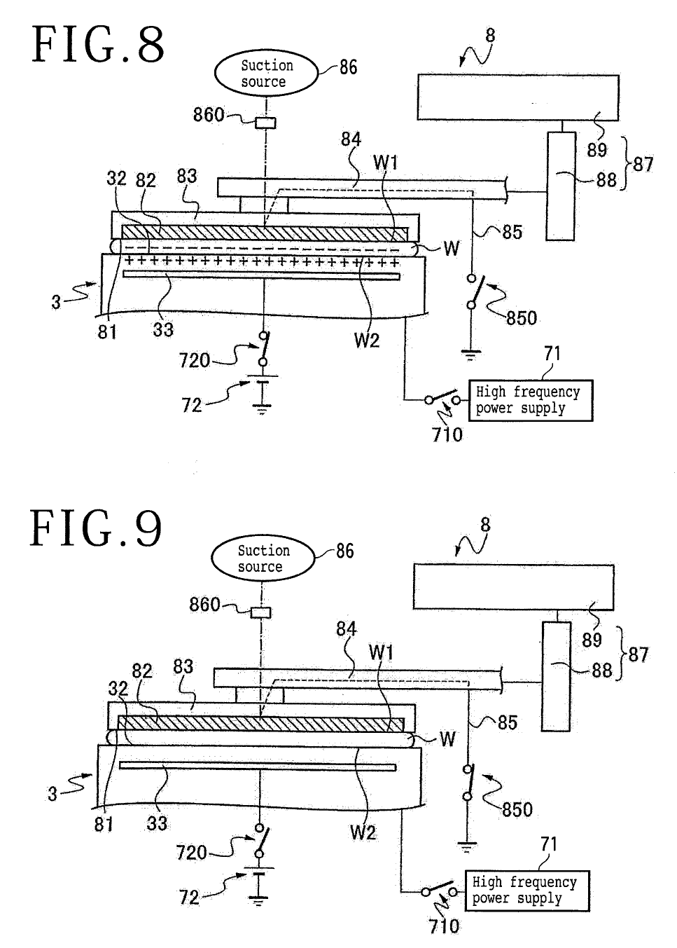

Then, the opening/closing port 222 depicted in FIG. 1 is opened to discharge the reaction gas to the outside therethrough, whereafter the shutter opening/closing means 26 moves down the shutter 25 to open the opening/closing port 24. Then, as depicted in FIG. 8, the loading/unloading moving means 89 of the loading means 8 moves the holding portion 82 and the frame member 83 forwardly into the chamber 2 through the opening/closing port 24, and the upward/downward moving means 88 moves down the holding portion 82 and the frame member 83 until the contacting portion 81 is brought into contact with the upper face W1 of the wafer W. Then, the valve 860 is turned on such that the holding portion 82 sucks and holds the upper face W1 of the wafer W. When the contacting portion 81 of the holding portion 82 is to be brought into contact with the wafer W, the switch 850 is turned off to establish a state in which the holding portion 82 and the ground are not connected to each other. Further, the switch 720 is kept on to maintain the state in which a positive voltage is applied to the lower electrode 33.

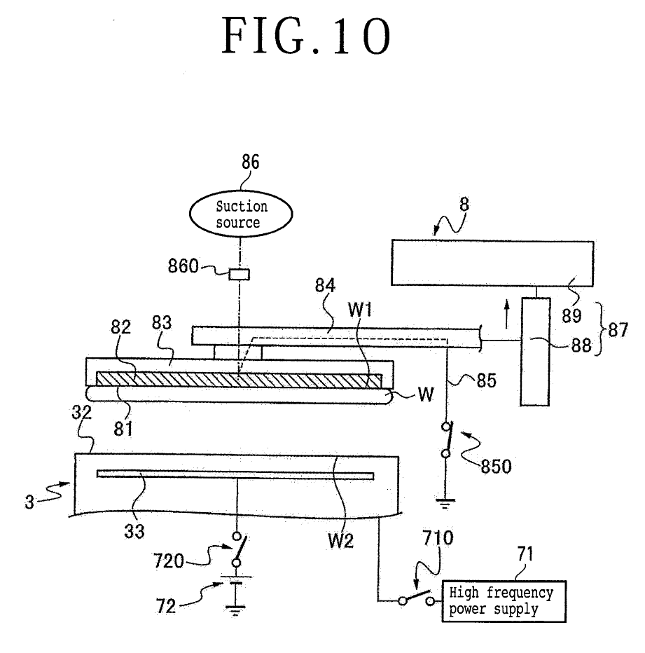

Then, as depicted in FIG. 9, the switch 720 is turned off to stop application of the positive voltage to the lower electrode 33. Then, the switch 850 is turned on to connect the holding portion 82 and the ground to each other. Consequently, the charge in the wafer W is removed and the attraction and holding of the wafer W by the electrostatic chuck 3 is cancelled. Then, if, in this state, the upward/downward moving means 88 moves up the holding portion 82 and the frame member 83 in the state in which the valve 860 remains on as depicted in FIG. 10, then the wafer W can be spaced away from the attraction face 32 of the electrostatic chuck 3. After the wafer W is spaced away from the attraction face 32, the switch 850 may be switched off. Further, it is more effective to provide a blow mechanism having an auxiliary role of jetting, when the wafer W is to be spaced away from the attraction face 32 of the electrostatic chuck 3, air through the suction holes 320 formed in the attraction face 32 such that the wafer W is spaced away from the attraction face 32 by the injection of air.

After the wafer W is spaced away from the attraction face 32, the loading/unloading moving means 89 unloads the holding portion 82 to the outside of the chamber 2 through the opening/closing port 24. By placing, when the wafer W held on the electrostatic chuck 3 is to be unloaded under the driving of the driving means 87 by the loading means 8 and spaced away from the electrostatic chuck 3, the holding portion 82 configuring the loading means 8 into a conducting state to the ground in this manner, positive charge in the upper face W1 side of the wafer W can be removed. Accordingly, even if means for lifting or moving up the wafer W from the electrostatic chuck 3 is not provided, it is possible to space and unload the wafer W away from the electrostatic chuck 3.

It is to be noted that, while, in the embodiment described hereinabove, unloading of a wafer W from the chamber 2 is performed using the loading means 8, unloading means different from the loading means 8 may be used for unloading of a wafer W from the chamber 2.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A decompression processing apparatus for performing a working process for a wafer with reaction gas in the form of plasma, comprising:
an electrostatic chuck having an attraction face formed from an upper face formed on an insulating material and having a lower electrode in the inside thereof, the electrostatic chuck being configured to electrostatically attract a wafer to the attraction face;
an upper electrode disposed above the electrostatic chuck in an opposing relationship to the attraction face of the electrostatic chuck;
a chamber configured to accommodate the electrostatic chuck and the upper electrode therein;
loading means for loading the wafer into the chamber and placing the wafer on the attraction face;
decompression means for decompressing the inside of the chamber;
gas supplying means for supplying the reaction gas into the chamber; and
high frequency voltage application means for applying a high frequency voltage to the electrostatic chuck to form plasma from the reaction gas supplied into the chamber;
the loading means including
a holding portion having a conductive contacting portion contacting with the upper face of the wafer and configured to hold the wafer thereon,
conduction means for establishing conduction of the holding portion to ground, and
driving means for placing the wafer held by the holding portion on the electrostatic chuck, wherein,
in a state in which the wafer held by the holding portion of the loading means contacts with the attraction face of the electrostatic chuck after the wafer is loaded into the chamber, the holding portion is connected to the ground by the conduction means and a direct current voltage is applied to the lower electrode, whereafter the holding portion cancels the attraction of the wafer and is moved away from the wafer such that the electrostatic chuck and the wafer are charged with electric charge different in polarity from each other thereby to allow the wafer to be attracted and held by the attraction face of the electrostatic chuck.

2. The decompression processing apparatus according to claim 1, wherein, in the state in which the wafer is attracted and held by the attraction face of the electrostatic chuck, a high frequency voltage is applied between the upper electrode and the lower electrode from the high frequency voltage application means to form plasma from the reaction gas supplied into the chamber such that the wafer is etched with the plasma.
